(19) United States
(12) Patent Application Publication
(10) Pub. No.: US 2012/0014071 A1
(43) Pub. Date: Jan. 19, 2012

(54) AMPLIFIER WITH SEALED ENTRY POINTS

(76) Inventor: Robert Louis Fils, Los Gatos, CA (US)

(21) Appl. No.: 12/837,712

(22) Filed: Jul. 16, 2010

(51) Int. Cl. H05K 5/00

(52) U.S. Cl. 361/724

(57) ABSTRACT

An ingress protection rated waterproof amplifier comprises an outer casing for covering a body of the amplifier. The outer casing comprises a top, a bottom, a left side, and a right side, wherein the left side and the right side comprise a sealing apparatus and a separatable endcap. The sealing apparatus and the end cap of the left side and the sealing apparatus and the end cap of the right side are separately removable from the top of the casing and the bottom of the casing. In some embodiments, the left side and the right side further comprise one or more additional sealing apparatus. In further embodiments, the amplifier comprises a series of controls for controlling the amplifier, which is sealed by a cover plate and a gasket. In some embodiments, the amplifier is a 12V DC amplifier.

### FIELD OF THE INVENTION

This invention relates generally to marine audio equipment. More specifically, this invention relates to marine amplifiers which are ingress protection rated for water intrusion.

### BACKGROUND OF THE INVENTION

Stereo systems including speakers and an amplifier are often installed on boats and other water craft in order to provide ambiance and enhance the experience of being on the water. Due to the nature of the outside use and other considerations, such electronics must be able to resist many elements, including water, wind, and vibration while remaining functional. There are many ingress protection rated marine amplifiers on the market. Current marine amplifiers often protect the amplifier from water and salt intrusion by conformal coating of the electronics. However, such a process is expensive and time consuming as the level application is controlled and undesired areas are masked. Additionally, conformal coating does not offer the same protection as completely sealing the amplifier.

### SUMMARY OF THE INVENTION

In one aspect, an ingress protection rated waterproof amplifier comprises an outer casing for covering a body of the amplifier. The outer casing comprises a top, a bottom, a left side, and a right side, wherein the left side and the right side comprise a sealing apparatus and a separatable endcap. In some embodiments, the sealing apparatus seals the amplifier against water intrusion. In some embodiments, the sealing apparatus is a rubber gasket. In further embodiments, the sealing apparatus is a cover plate. In still further embodiments, the sealing apparatus and the end cap of the left side and the sealing apparatus and the end cap of the right side are separately removable from the top of the casing and the bottom of the casing. In some embodiments, the left side and the right side further comprise one or more additional sealing apparatus. In some embodiments, one or more of the left side and the right side further comprises a sealable wire clamp. In further embodiments, the amplifier comprises a series of controls for controlling the amplifier, wherein the series of controls is sealed by a cover plate and a gasket. In some embodiments, the amplifier is a 12V DC amplifier. In some embodiments, the exterior of the amplifier comprises an anti-corrosive material. In further embodiments, the exterior of the amplifier comprises an impact resistant material.

In another aspect, a removable waterproof amplifier cover comprises a top panel, a bottom panel, a right panel, and a left panel wherein the right panel and the left panel comprise a sealing apparatus and a separatable endcap, and further wherein the amplifier is sealed against water intrusion when the amplifier is placed within the waterproof cover. In some embodiments, the sealing apparatus is a rubber gasket. In some embodiments, the sealing apparatus is a cover plate. In further embodiments, the sealing apparatus and the end cap of the left side and the sealing apparatus and the end cap of the right side are separately removable from the top panel and the bottom panel. In some embodiments, the left side and the right side further comprise one or more additional sealing apparatus. In some embodiments, one or more of the left side and the right side further comprises a sealable wire clamp. In further embodiments, the amplifier comprises a series of controls for controlling the amplifier, wherein the series of controls is sealed by a cover plate and a gasket. In some embodiments the waterproof cover is ingress protection rated. In further some embodiments the cover is configured to hold a 12V DC amplifier. In some embodiments, the exterior of the cover comprises an anti-corrosive material. In further embodiments the exterior of the cover comprises an impact resistant material.

In yet another aspect an ingress protection rated stereo component comprises an outer casing comprising removable endcaps and a heat sink, wherein the outer casing seals the interior of the stereo component against water instrusion. In some embodiments the interior of the stereo component is sealed by a cover plate and a gasket. In some embodiments the outer casing comprises a non-corrosive material. In some embodiments the stereo component is a 12V DC amplifier. In further embodiments the stereo component comprises a series of controls for controlling the amplifier, wherein the series of controls is sealed by a cover plate and a gasket. In some embodiments the exterior of the cover comprises an anti-corrosive material. In some embodiments the exterior of the cover comprises an impact resistant material.

### BRIEF DESCRIPTION OF THE DRAWINGS

FIG. 1 shows a front perspective view of an amplifier with sealed entry points in accordance with some embodiments.

FIG. 2 shows a back perspective view of an amplifier with sealed entry points in accordance with some embodiments.

FIG. 3 shows a partially exploded front perspective view of an amplifier with sealed entry points in accordance with some embodiments.

FIG. 4 shows a partially exploded bottom perspective view of an amplifier with sealed entry points in accordance with some embodiments.

FIG. 5 shows a partially exploded bottom perspective view of an amplifier with sealed entry points in accordance with some embodiments.

FIG. 6 shows a top view of an amplifier with sealed entry points in accordance with some embodiments.

FIG. 7 shows a bottom perspective view of an amplifier with sealed entry points in accordance with some embodiments.

FIG. 8 shows a front perspective view of an amplifier cover with sealed entry points in accordance with some embodiments.

FIG. 9 shows a partially exploded front perspective view of an amplifier cover with sealed entry points in accordance with some embodiments.

### DETAILED DESCRIPTION OF THE PREFERRED EMBODIMENT

In the following description, numerous details and alternatives are set forth for purpose of explanation. However, one of ordinary skill in the art will realize the invention is able to be practiced without the use of these specific details. For instance, the figures and description below often refer to an amplifier. However, one of ordinary skill in the art will recognize that some embodiments of the invention are able to be practiced with other electronic systems and components. Additionally, throughout the description similar components are similarly marked in order to aid comprehension.

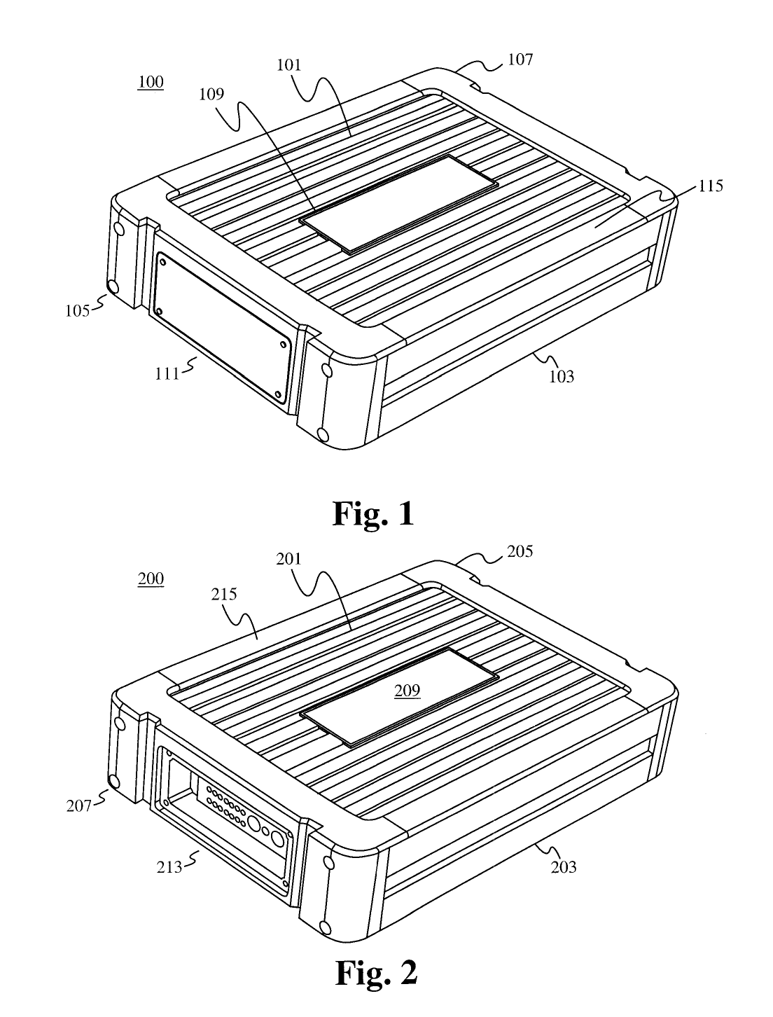

Referring now to FIG. 1, an amplifier 100 with sealed entry points is depicted therein. The amplifier 100 comprises a top 101, a bottom 103, a left side 105 and a right side 107. In some embodiments, the amplifier 100 further comprises one or more of a crossover cover 111, a name badge 109, and one or more heat sinks 115. As discussed further below, the top 101, the bottom 103, the left side 105 and the right side 107 as well as the crossover cover 111, and the one or more heat sinks 115 seal the amplifier 100 against water intrusion. The crossover cover 111 covers the controls (not shown) of the amplifier 100. For example, in some embodiments, a user is able to adjust the crossover points, bridging, and gains of the amplifier 100 using the controls. In some embodiments, a user is able to use the controls to control other features of the amplifier 100. In some embodiments, a user is able to use a remote control device (not shown) to control features of the amplifier 100. Alternatively, in some embodiments, a user is able to remove the crossover cover 111 in order to operate the controls. In some embodiments, the amplifier 100 further comprises waterproof connectors (not shown) for power and speaker leads. In some of these embodiments, the connectors are detachable.

In FIG. 1, the heat sink 115 is shown on the front of the amplifier 100. However, one of ordinary skill in the art will recognize that the heat sink 115 is able to be placed at other positions on the exterior of the amplifier 100. In some embodiments, the amplifier 100 is able to comprise one or more additional heat sinks 115 as needed. In some embodiments, the exterior of the amplifier 100 comprises an anti-corrosive material. In some embodiments, the exterior of the amplifier 100 comprises an impact resistant material to protect the amplifier from vibrations, shock, and impact. In some embodiments the amplifier 100 comprises a 12V DC amplifier. In some embodiments, the amplifier is an amplifier which is converted from 12V DC to 36V DC. However, the amplifier 100 is able to comprise any size as known in the art.

FIG. 2 shows a back perspective view of an amplifier 200. The amplifier 200 comprises a top 201, a bottom 203, a left side 205 and a right side 207, a name badge 209, one or more heat sinks 215, and a sealable wire clamp 213. In some embodiments, the sealable wire clamp 213 is further covered by one or more of a gasket and a coverplate.

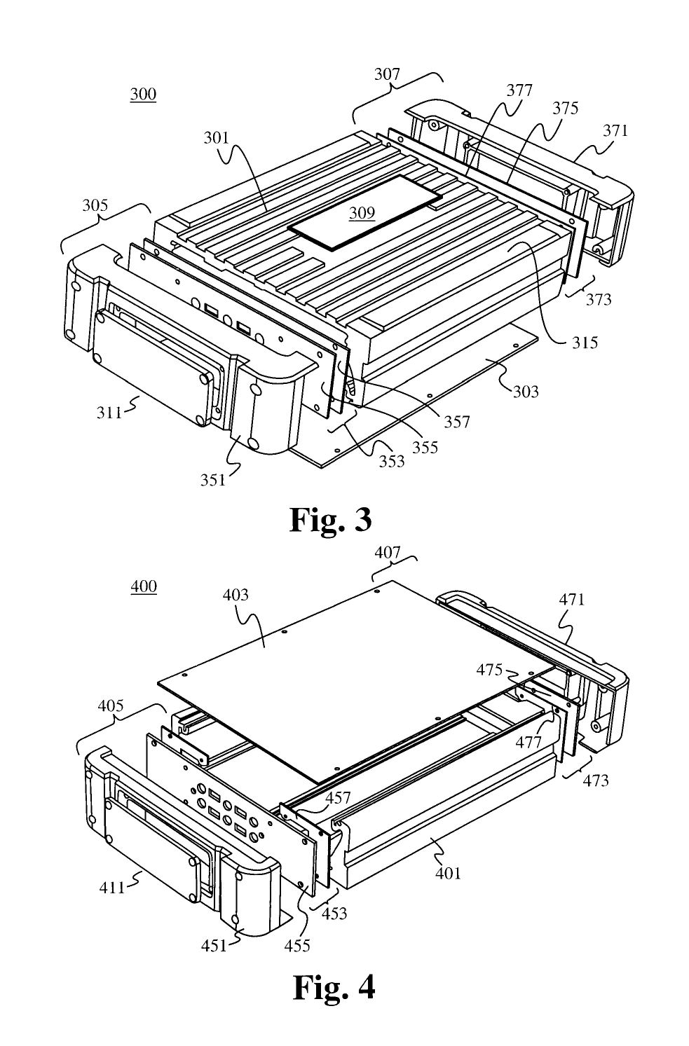

FIG. 3 shows a partially exploded front perspective view of an amplifier 300 with sealed entry points in accordance with some embodiments. As discussed above, the amplifier 300 comprises a top 301, a bottom 303, a left side 305, a right side 307, a name badge 309, a crossover cover 311 and one or more heat sinks 315. The bottom 303, the left side 305 and the right side 307 as well as the crossover cover 311, and the one or more heat sinks 315 seal the amplifier 300 against water intrusion.

The left side 305 comprises a sealing apparatus 353 and a separatable endcap 351. In some embodiments, the sealing apparatus 353 seals the left side 305 of the amplifier 300 against water intrusion. In some embodiments, the sealing apparatus 353 comprises a side panel 355 and a washer 357. In some embodiments, the sealing apparatus 353 comprises only a side panel 355. In further embodiments, the sealing apparatus 353 comprises only a washer 357. In some embodiments, the side panel 355 and the washer 357 are a cover plate and a rubber gasket, respectively. In some embodiments, the side panel 355 comprises one or more of plastic, aluminum, iron, acrylic, and metal. However, the side panel 355 is able to comprise any compatible material as known in the art. As shown in FIG. 3, in some embodiments, the endcap 351 fits over the sealing apparatus 353 to form the left side 305 of the amplifier 300. In some embodiments, the sealing apparatus 353 and the endcap 351 are separately removable from the top 301 and the bottom 303 of the amplifier 300.

Similarly, the right side 307 comprises a sealing apparatus 373 and a separatable endcap 371. In some embodiments, the sealing apparatus 373 seals the right side 307 of the amplifier 300 against water intrusion. In some embodiments, the sealing apparatus 373 comprises a side panel 375 and a washer 377. In some embodiments, the sealing apparatus 373 comprises only a side panel 375. In further embodiments, the sealing apparatus 373 comprises only a washer 377. In some embodiments, the side panel 375 and the washer 377 are a cover plate and a rubber gasket, respectively. In some embodiments, the side panel 375 comprises one or more of plastic, aluminum, iron, acrylic, and metal. However, the side panel 375 is able to comprise any compatible material as known in the art. As shown in FIG. 3, in some embodiments, the endcap 371 fits over the sealing apparatus 373 to form the right side 307 of the amplifier 300. In some embodiments, the sealing apparatus 373 and the endcap 371 are separately removable from the top 301 and the bottom 303 of the amplifier 300.

As further shown in FIG. 3, the amplifier 300 comprises a crossover cover 311 and a heat sink 315. In some embodiments, the heat sink 315 comprises a gasket. In some embodiments, the heat sink 315 comprises a coverplate and a gasket. In some embodiments, the crossover cover 311 comprises one or more of a cover plate and a gasket. In further embodiments, the cross over cover 311 comprises a cover plate and a gasket. As described above, the crossover cover 311 seals the controls of the amplifier from water intrusion and the gasket of the heat sink seals the heat sink 315 against water intrusion.

FIG. 4 shows a partially exploded bottom perspective view of the amplifier 400 in accordance with some embodiments. As shown in FIG. 4, the amplifier 400 comprises a bottom 403, a top 401, a left side 405 and a right side 407. The bottom 403, the top 401, the left side 405 and the right side 407 are configured to be coupled by one or more of a threaded screw, snap fit, rivet, and glue. However, one of ordinary skill in the art will recognize that the bottom 403, the top 401, the left side 405 and the right side 407 are able to be coupled together by any mechanism as known in the art. In some embodiments, the sealing apparatus 453 couples to the top 401 and the bottom 403 of the amplifier 400 by a threaded screw fit and the separatable endcap 451 snap fits over the sealing apparatus 453 to be coupled to the top 401 and the bottom 403 of the amplifier 400. In further embodiments, the separatable endcap 451 fits over the sealing apparatus 453 and couples to the top 401 and the bottom 403 of the amplifier 400 by one or more of a threaded screw and a rivet. In some embodiments, sealing apparatus 453 further comprises one or more of silicone and epoxy in order to further seal the components of amplifier 400. In some embodiments, the components are encapsulated using one or more of silicone and epoxy before the sealing apparatus 453 is coupled to the top 401 and the bottom 403 of the amplifier 400.

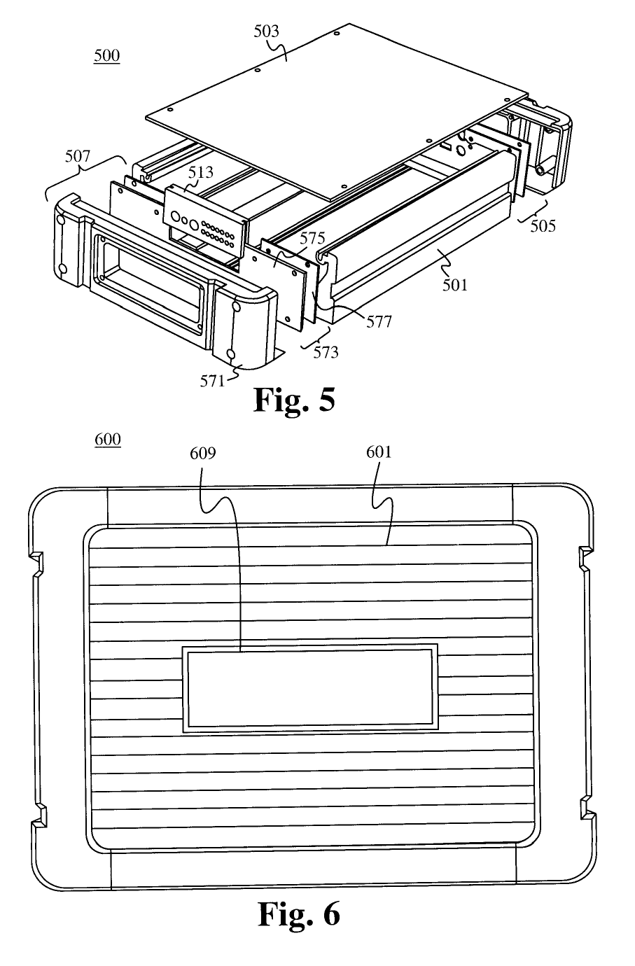

FIG. 5 shows a partially exploded bottom perspective view of the amplifier 500 in accordance with some embodiments. As shown in FIG. 5, the amplifier 500 comprises a bottom 503, a top 501, a left side 505 and a right side 507. FIG. 5, shows the amplifier 500 with the right side 507 in front. As shown in FIG. 5, in some embodiments, the amplifier further comprises a sealable wire clamp 513. In some embodiments, the sealable wire clamp 513 couples with the sealing apparatus 573 of the right side 507. As described in relation to the left side 505, in some embodiments, the sealing apparatus 573 couples to the top 501 and the bottom 503 of the amplifier 500 by a threaded screw fit and the separatable endcap 571 snap fits over the sealing apparatus 573 to be coupled to the top 501 and the bottom 503 of the amplifier 500. In further embodiments, the separatable endcap 571 fits over the sealing apparatus 573 and couples to the top 501 and the bottom 503 of the amplifier 500 by one or more of a threaded screw and a rivet. In some embodiments, sealing apparatus 573 further comprises one or more of silicone and epoxy in order to further seal the components of amplifier 500. In some embodiments, the components are encapsulated using one or more of silicone and epoxy before the sealing apparatus 573 is coupled to the top 501 and the bottom 503 of the amplifier 500.

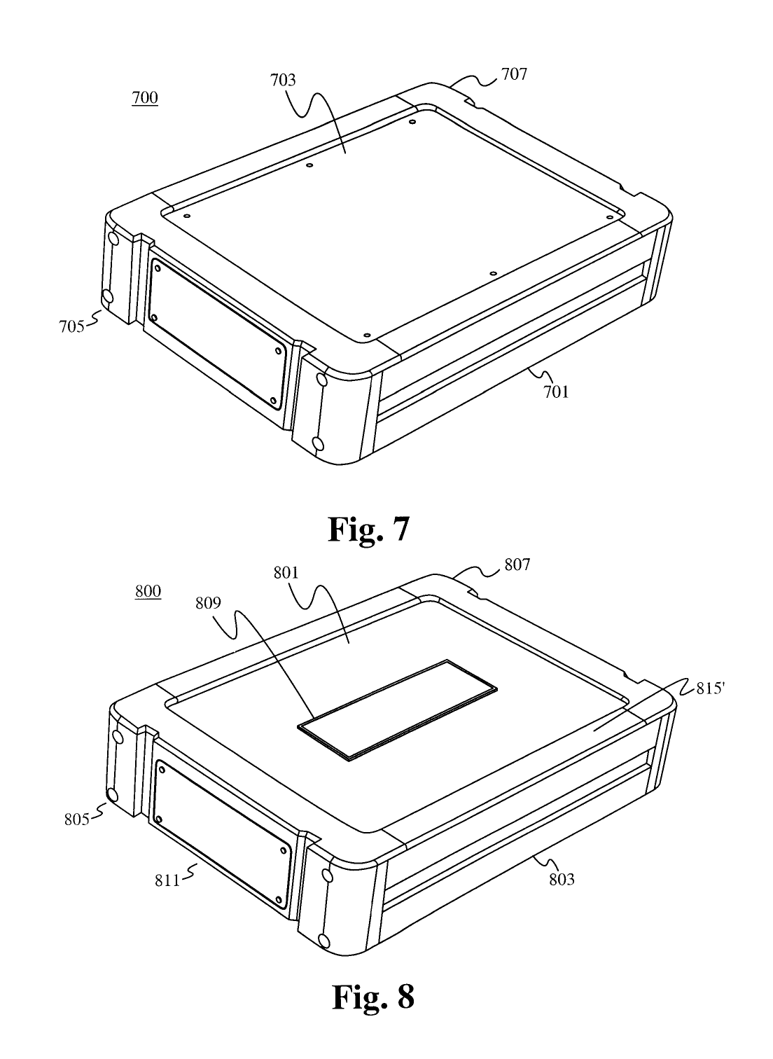

FIG. 6 shows a top view of an amplifier 600 with sealed entry points in accordance with some embodiments. FIG. 6 shows the top 601 and the name badge 609 of the amplifier 600. As shown in FIG. 6, the top 601 of the amplifier 600 seals it from water intrusion.

FIG. 7 shows a bottom perspective view of an amplifier 700 with sealed entry points in accordance with some embodiments. As shown in FIG. 7, the amplifier 700 comprises a bottom 703, a top 701, a left side 705 and a right side 707. The bottom 703, the top 701, the left side 705 and the right side 707 seal the amplifier 700 from water intrusion. As described above, the bottom 703, the top 701, the left side 705 and the right side 707 are able to be coupled by one or more of a threaded screw, snap fit, rivet, and glue. However, one of ordinary skill in the art will recognize that the bottom 703, the top 701, the left side 705 and the right side 707 are able to be coupled together by any mechanism as known in the art. Particularly, by coupling the amplifier with the respective pieces, the entry points of the amplifier are sealed from water intrusion.

In operation, the amplifier with sealed entry points enables a user to safely utilize the amplifier on a boat or other water craft without worrying that the amplifier will be damaged by water or salt intrusion. By completely sealing the entry points of the amplifier at the point of manufacture an inexpensive ingress protection rated amplifier is provided that is able to be utilized in conjunction with marine stereo systems. In some embodiments, the amplifier is ingress protection 55 rated. In further embodiments, the amplifier is ingress protection 56 rated. However, the amplifier is able to be ingress protection rated to any level as known in the art.

In another aspect, FIG. 8 shows a front perspective view of an amplifier cover 800 with sealed entry points in accordance with some embodiments. The amplifier cover 800 comprises a top panel 801, a bottom panel 803, a left panel 805 and a right panel 807. In some embodiments, the cover 800 further comprises one or more of a crossover cover 811, and a name badge 809. In some embodiments, the cover 800 also comprises one or more heat sink gaskets 815′. The top panel 801, the bottom panel 803, the left panel 805 and the right panel 807 as well as the crossover cover 811, and the one or more heat sink gaskets 815′ of the cover 800 seal an amplifier (not shown) against water intrusion. Particularly, a user is able to place an amplifier within the interior of the cover 800 to seal the amplifier and protect against water intrusion while boating or on the water.

In some embodiments, the crossover cover 811 covers the controls (not shown) of the amplifier. In some embodiments, a user is able to use a remote control device (not shown) to control features of the amplifier. Alternatively, in some embodiments, a user is able to remove the crossover cover 811 in order to operate the controls of the amplifier. In FIG. 8, the one or more heat sink gaskets 815′ is shown on the front of the cover 800. However, one of ordinary skill in the art will recognize that the one or more heat sink gaskets 815′ is able to be placed at other positions on the exterior of the cover 800 according to the position of the heat sink on the amplifier that a user desires to protect. In some embodiments, the exterior of the cover 800 comprises an anti-corrosive material. In some embodiments, the exterior of the cover 800 comprises an impact resistant material to protect the amplifier from vibrations, shock, and impact. In some embodiments the cover 800 fits over a 12V DC amplifier. In some embodiments, the cover 800 fits over an amplifier which is converted from 12V DC to 36V DC. However, the cover 800 is designed to fit any sized amplifier as known in the art. In some embodiments, the cover 800 is ingress protection 55 rated. In further embodiments, the cover 800 is ingress protection 56 rated. However, the cover 800 is able to be ingress protection rated to any level as known in the art.

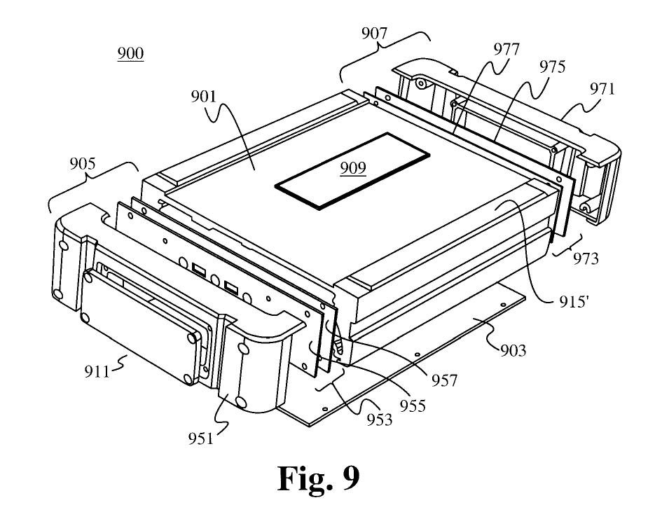

FIG. 9 shows a partially exploded front perspective view of a cover 900 for an amplifier with sealed entry points in accordance with some embodiments. As discussed above, the cover 900 comprises a top panel 901, a bottom panel 903, a left panel 905 and a right panel 907, a name badge 909, a crossover cover 911 and one or more heat sink gaskets 915′. The bottom panel 903, the left panel 905 and the right panel 907 as well as the crossover cover 911, and the one or more heat sink gaskets 915′ seal the cover 900 against water intrusion. In some embodiments, the cover 900 further comprises waterproof connectors (not shown) for power and speaker leads. In some of these embodiments, the connectors are detachable.

The left panel 905 comprises a sealing apparatus 953 and a separatable endcap 951. In some embodiments, the sealing apparatus 953 seals the left panel 905 of the cover 900 against water intrusion. In some embodiments, the sealing apparatus 953 comprises a side panel 955 and a washer 957. In some embodiments, the sealing apparatus 953 comprises only a side panel 955. In further embodiments, the sealing apparatus 953 comprises only a washer 957. In some embodiments, the side panel 955 and the washer 957 are a cover plate and a rubber gasket, respectively. In some embodiments, the side panel 955 comprises one or more of plastic, aluminum, iron, acrylic, and metal. However, the side panel 955 is able to comprise any compatible material as known in the art. As shown in FIG. 9, in some embodiments, the endcap 951 fits over the sealing apparatus 953 to form the left panel 905 of the cover. In some embodiments, the sealing apparatus 953 and the endcap 951 are separately removable from the top 901 and the bottom 903 of the cover 900.

Similarly, the right panel 907 comprises a sealing apparatus 973 and a separatable endcap 971. In some embodiments, the sealing apparatus 973 seals the right panel 907 of the cover 900 against water intrusion. In some embodiments, the sealing apparatus 973 comprises a side panel 975 and a washer 977. In some embodiments, the sealing apparatus 953 comprises only a side panel 975. In further embodiments, the sealing apparatus 973 comprises only a washer 977. In some embodiments, the side panel 975 and the washer 977 are a cover plate and a rubber gasket, respectively. In some embodiments, the side panel 975 comprises one or more of plastic, aluminum, iron, acrylic, and metal. However, the side panel 975 is able to comprise any compatible material as known in the art. As shown in FIG. 9, in some embodiments, the endcap 971 fits over the sealing apparatus 973 to form the right panel 907 of the cover 900. In some embodiments, the sealing apparatus 973 and the endcap 971 are separately removable from the top 901 and the bottom panel 903 of the cover 900.

As further shown in FIG. 9, the cover 900 comprises a crossover cover 911 and a heat sink gasket 915′. In some embodiments, the crossover cover 911 comprises one or more of a cover plate and a gasket. In further embodiments, the crossover cover 911 comprises a cover plate and a gasket. As described above, the crossover cover 911 seals the controls of the amplifier from water intrusion and the heat sink gasket 915′ seals the heat sink against water intrusion.

The bottom panel 903, the top panel 901, the left panel 905 and the right panel 907 are configured to be coupled by one or more of a threaded screw, snap fit, rivet, and glue. However, one of ordinary skill in the art will recognize that the bottom panel 903, the top panel 901, the left panel 905 and the right panel 907 are able to be coupled together by any mechanism as known in the art. In some embodiments, the sealing apparatus 953 is coupled to the top panel 901 and the bottom panel 903 of the cover 900 by a threaded screw fit and the separatable endcap 951 snap fits over the sealing apparatus 953 to be coupled to the top panel 901 and the bottom panel 903 of the cover 900. In further embodiments, the separatable endcap 951 fits over the sealing apparatus 953 and is coupled to the top panel 901 and the bottom panel 903 of the cover 900 by one or more of a threaded screw and a rivet. In some embodiments, sealing apparatus 953 further comprises one or more of silicone and epoxy in order to further seal the components of the cover 900.

In operation, the cover for an amplifier with sealed entry points enables a user to protect an amplifier from water and salt intrusion. Additionally, the cover enables a user to utilize different amplifiers on a boat or other water craft. For example, a user is able to change or upgrade amplifiers as a corresponding stereo component is changed while using the same protective cover. Consequently, the cover enables a user to protect different amplifiers at minimal cost. Accordingly, the cover for an amplifier with sealed entry points described herein has numerous advantages.

The invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modifications area able to be made in the embodiment chosen for illustration without departing from the spirit and scope of the invention. Specifically, it will be apparent that design for the amplifier with sealed entry points and the cover for an amplifier with sealed entry points is able to be incorporated within any ingress protection rated stereo component. Further, it will be apparent to one of ordinary skill in the art that the precise structure of the device is able to be substantially varied to accommodate various electronic components while still being compatible with the invention. Consequently, the claims should be broadly construed, consistent with the spirit and scope of the invention, and should not be limited to their exact, literal meaning.

What is claimed is:

1. An ingress protection rated waterproof amplifier comprising:
a. an outer casing for covering a body of the amplifier, the outer casing comprising;
i. a top;
ii. a bottom;
iii. a left side; and
iv. a right side;
wherein the left side and the right side comprise a sealing apparatus and a separatable endcap.

2. The amplifier of claim 1, wherein the sealing apparatus seals the amplifier against water intrusion.

3. The amplifier of claim 1, wherein the sealing apparatus is a rubber gasket.

4. The amplifier of claim 1, wherein the sealing apparatus is a cover plate.

5. The amplifier of claim 1, wherein the sealing apparatus and the end cap of the left side and the sealing apparatus and the end cap of the right side are separately removable from the top of the casing and the bottom of the casing.

6. The amplifier of claim 1, wherein the left side and the right side further comprise one or more additional sealing apparatus.

7. The amplifier of claim 1, wherein one or more of the left side and the right side further comprises a sealable wire clamp.

8. The amplifier of claim 1, further comprising a series of controls for controlling the amplifier, wherein the series of controls is sealed by a cover plate and a gasket.

9. The amplifier of claim 1, wherein the amplifier is a 12V DC amplifier.

10. The amplifier of claim 1, wherein the exterior of the amplifier comprises an anti-corrosive material.

11. The amplifier of claim 1, wherein the exterior of the amplifier comprises an impact resistant material.

12. A removable waterproof amplifier cover, comprising:
a. a top panel;
b. a bottom panel;
c. a right panel; and
d. a left panel;
wherein the right panel and the left panel comprise a sealing apparatus and a separatable endcap, and further wherein the amplifier is sealed against water intrusion when the amplifier is placed within the waterproof cover.

13. The amplifier cover of claim 12, wherein the sealing apparatus is a rubber gasket.

14. The amplifier cover of claim 12, wherein the sealing apparatus is a cover plate.

15. The amplifier cover of claim 12 wherein the sealing apparatus and the end cap of the left side and the sealing apparatus and the end cap of the right side are separately removable from the top panel and the bottom panel.

16. The amplifier cover of claim 12, wherein the left side and the right side further comprise one or more additional sealing apparatus.

17. The amplifier cover of claim 12, wherein one or more of the left side and the right side further comprises a sealable wire clamp.

18. The amplifier cover of claim 12, further comprising a series of controls for controlling the amplifier, wherein the series of controls is sealed by a cover plate and a gasket.

19. The amplifier cover of claim 12, wherein the waterproof cover is ingress protection rated.

20. The amplifier cover of claim 12, wherein the cover is configured to hold a 12V DC amplifier.

21. The amplifier cover of claim 12, wherein the exterior of the cover comprises an anti-corrosive material.

22. The amplifier cover of claim 12, wherein the exterior of the cover comprises an impact resistant material.

23. An ingress protection rated stereo component comprising:
a. an outer casing comprising removable endcaps and a heat sink, wherein the outer casing seals the interior of the stereo component against water instrusion.

24. The stereo component of claim 23, wherein the interior of the stereo component is sealed by a cover plate and a gasket.

25. The stereo component of claim 23, wherein the outer casing comprises a non-corrosive material.

26. The stereo component of claim 23, wherein the stereo component is a 12V DC amplifier.

27. The stereo component of claim 23, further comprising a series of controls for controlling the stereo component, wherein the series of controls is sealed by a cover plate and a gasket.

28. The stereo component of claim 23, wherein the exterior of the cover comprises an anti-corrosive material.

29. The stereo component cover of claim 23, wherein the exterior of the cover comprises an impact resistant material.
